(19) United States
(12) Patent Application Publication
(10) Pub. No.: US 2011/0227044 A1
(43) Pub. Date: Sep. 22, 2011

(54) TRANSISTOR AND METHOD FOR MANUFACTURING THE SAME

(75) Inventors: Shigeru Kawanaka, Yokohama-shi (JP); Kanna Adachi, Chigasaki-shi (JP); Toshitaka Miyata, Yokohama-shi (JP); Hideji Tsujii, Yokohama-shi (JP)

(73) Assignee: KABUSHIKI KAISHA TOSHIBA, Tokyo (JP)

(21) Appl. No.: 13/046,940

(22) Filed: Mar. 14, 2011

(30) Foreign Application Priority Data
Mar. 18, 2010 (JP) 2010-62855

(51) Int. Cl. H01L 29/08; B82Y 99/00

(52) U.S. Cl. 257/29; 257/E29.068; 977/755; 977/734

(57) ABSTRACT

In one embodiment, a transistor includes: a substrate; a source electrode formed on the substrate; a drain electrode formed on the substrate; a graphene film formed between the source electrode and the drain electrode, the graphene film having a semiconductor region including a source side end and a conductor region including a drain side end, a width of the source side end of the graphene film in a channel width direction being narrower than a width of the drain side end of the graphene film in the channel width direction; and a gate electrode formed via a gate insulating film on the semiconductor region of the graphene film and the conductor region of the graphene film. The source electrode is connected to the source side end of the graphene film with a Schottky contact, and the drain electrode is connected to the drain side end of the graphene film with an ohmic contact.

### CROSS-REFERENCE TO RELATED APPLICATION

This application is based upon and claims the benefit of priority from prior Japanese Patent Application No. 2010-62855, filed on Mar. 18, 2010, the entire contents of which are incorporated herein by reference.

### FIELD

Embodiments of the present invention relate to a transistor and a method for manufacturing the same.

### BACKGROUND

There has been conventionally known, as a transistor in the related art, a field effect type graphene transistor using a graphene film having a narrower width of a channel layer on a drain side than that on a source side. In general, a single graphene film has no band gap. However, when the width of graphene becomes as narrow as under about 10 nm, a band gap appears. It has been known that as the width becomes narrower, the width of the band gap becomes larger.

In such a semiconductor device as described above, the band gap is increased by reducing the width of a graphene film on the drain side, thereby enhancing voltage withstand characteristics in a region between a channel and a drain, to which a large voltage is applied. In addition, the band gap is reduced by increasing the width on the source side, thereby enhancing a carrier mobility between a source and the channel.

### BRIEF DESCRIPTION OF THE DRAWINGS

FIG. 1 is a cross-sectional view showing a transistor in the embodiment according to the present invention;

FIG. 2A is a top view exemplifying a pattern shape of a graphene film in the embodiment;

FIG. 2B is a top view exemplifying another pattern shape of a graphene film in the embodiment;

FIG. 3 is a diagram schematically illustrating a band structure of the graphene film shown in FIG. 2A;

FIG. 4 is a top view exemplifying another pattern shape of the graphene film in the embodiment;

FIG. 5 is a diagram schematically illustrating a band structure of the graphene film shown in FIG. 4;

FIG. 6 is a top view exemplifying a further pattern shape of the graphene film in the embodiment;

FIG. 7 is a diagram schematically illustrating a band structure of the graphene film shown in FIG. 6; and

FIGS. 8A to 8D are cross-sectional views illustrating a process for manufacturing the transistor in the embodiment according to the present invention.

### DETAILED DESCRIPTION

In one embodiment, a transistor includes: a substrate; a source electrode formed on the substrate; a drain electrode formed on the substrate; a graphene film formed between the source electrode and the drain electrode, the graphene film having a semiconductor region including a source side end and a conductor region including a drain side end, a width of the source side end of the graphene film in a channel width direction being narrower than a width of the drain side end of the graphene film in the channel width direction; and a gate electrode formed via a gate insulating film on the semiconductor region of the graphene film and the conductor region of the graphene film. The source electrode is connected to the source side end of the graphene film with a Schottky contact, and the drain electrode is connected to the drain side end of the graphene film with an ohmic contact.

### Embodiments

### (Configuration of Transistor)

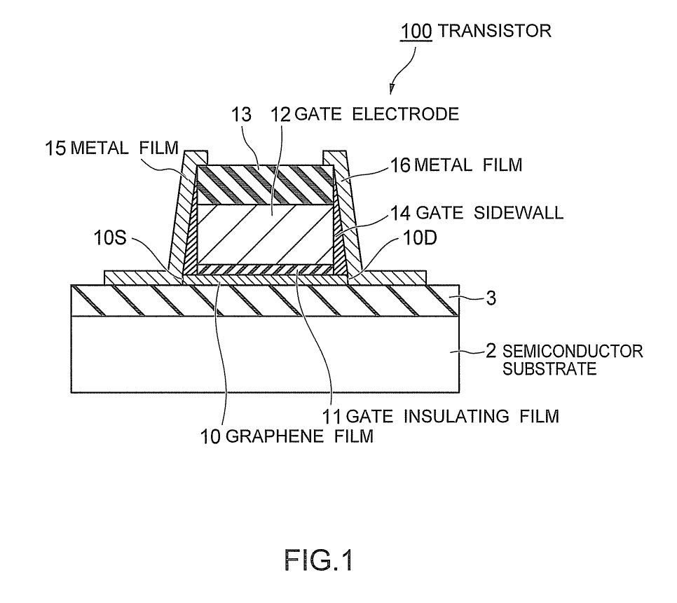

FIG. 1 is a cross-sectional view showing a transistor 100 in the embodiment according to the present invention. In the transistor 100, a tunnel current passing through a Schottky barrier is utilized for a switching operation.

The transistor 100 includes: a semiconductor substrate 2; an insulating film 3 formed on the semiconductor substrate 2; a graphene film 10 formed on the insulating film 3; a gate electrode 12 formed on the graphene film 10 via a gate insulating film 11; a cap film 13 formed on the gate electrode 12; a gate side wall 14 formed at the side surface of the gate electrode 12; a metal film 15 connected to a source side end 10S of the graphene film 10; and another metal film 16 connected to a drain side end 10D of the graphene film 10.

The semiconductor substrate 2 is made of, for example, a Si-based crystal such as Si crystal.

The insulating film 3 is made of, for example, an insulating material such as SiO₂.

The gate insulating film 11 is made of, for example, an insulating material such as SiO₂, SiN, or SiON or a high dielectric material such as HfSiON or AlOx.

The gate electrode 12 is made of, for example, a Si-based polycrystal such as polycrystalline Si containing conductive impurities, metal, or a laminate thereof.

The cap film 13 is made of an insulating material such as SiN.

The gate side wall 14 is made of an insulating material such as SiO₂ or SiN.

The metal film 15 functioning as a source electrode and the other metal film 16 functioning as a drain electrode are made of metal such as Pd.

The graphene film 10 is made of one to several tens of graphene sheets and has varistically conductive characteristics. Here, the graphene sheet is a single graphite film.

It has been known that the graphene sheet having a sufficient width does not have any band gap, and therefore, exhibits conductive properties; in contrast, a narrow graphene sheet called a graphene nano ribbon has a band gap, and therefore, exhibits semiconductive properties.

Such properties are caused by a difference in energy state between the end (i.e., an edge) of the graphene sheet and the inside thereof. In the wide region of graphene sheet, a rate (i.e., an area ratio) occupied by the end of the graphene sheet having a peculiar energy state is small, and therefore, there is no change in conductive property of the graphene sheet. In contrast, in the narrow region of graphene sheet, the rate occupied by the end of the graphene sheet to entire area is large, and therefore, semiconductive properties appear.

The width of the graphene sheet exhibiting the semiconductive properties is, for example, 10 nm or narrower, although it depends upon the end state (i.e., the arrangement of carbon atoms appearing at the end).

The width of the drain side end 10D of the graphene film 10 is wide in a channel width direction (e.g., wider than 10 nm). A region on the drain side including the drain side end 10D exhibits the conductive properties.

In contrast, the width of the source side end 10S in the channel width direction is narrower than that of the drain side end 10D (e.g., 10 nm or narrower). A region on the source side including the source side end 10S exhibits the semiconductive properties.

As a consequence, the metal film 16 connected to the drain side end 10D of the graphene film 10 forms an ohmic contact with the graphene film 10. In contrast, the metal film 15 connected to the source side end 10S of the graphene film 10 forms a Schottky contact with the graphene film 10.

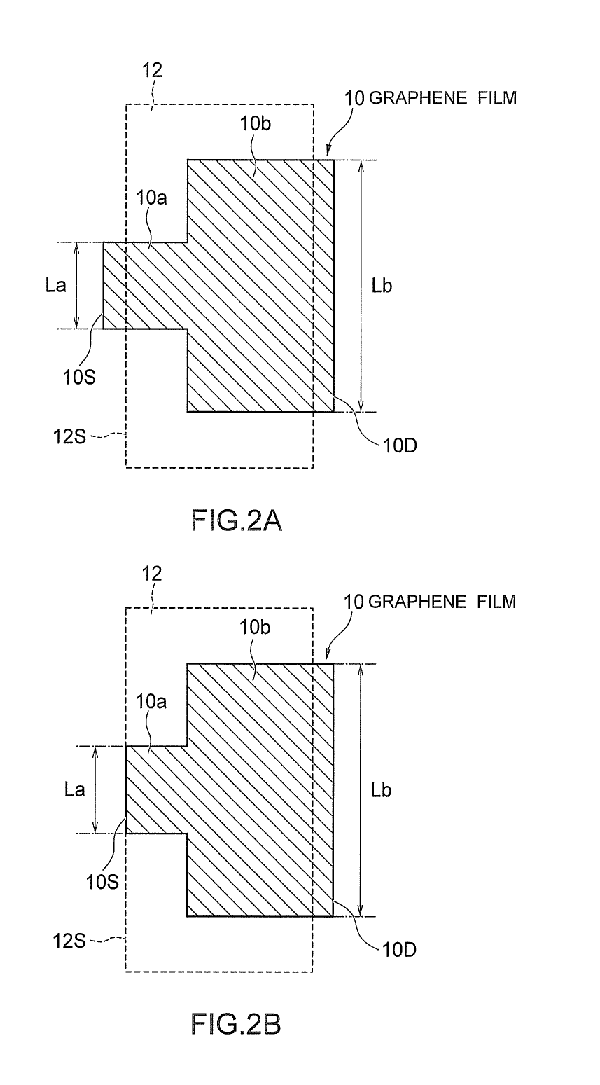

FIG. 2A is a top view exemplifying a pattern shape of the graphene film 10. FIG. 2B is a top view exemplifying another pattern shape of the graphene film 10. Dot lines in FIGS. 2A and 2B show the position of the gate electrode 12 over the graphene film 10.

The graphene film 10 includes a semiconductor region 10a on the source side and a conductor region 10b on the drain side. A width La of the semiconductor region 10a in the channel width direction (i.e., vertically in FIGS. 2A and 2B) is narrower than a width Lb of the conductor region 10b in the channel width direction. In one example, the width La is narrower than 10 nm whereas the width Lb is 10 nm or wider. It is preferable that the semiconductor region 10a should have a band gap of 0.3 eV or more such that the transistor 100 has satisfactory cut-off characteristics.

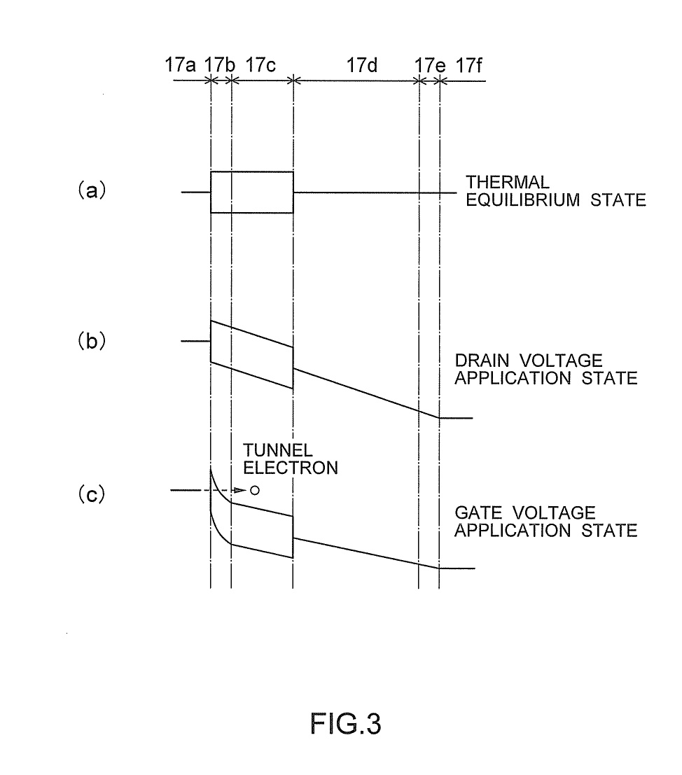

FIG. 3 is diagrams schematically illustrating a band structure of the graphene film 10 shown in FIG. 2A. The horizontal axis in FIG. 3 represents a position in a channel direction (laterally in FIG. 2A).

A region 17b represents a region under the gate side wall 14 in the semiconductor region 10a; a region 17c represents a region under the gate electrode 12 in the semiconductor region 10a; a region 17d represents a region under the gate electrode 12 in the conductor region 10b; and a region 17e represents a region under the gate side wall 14 in the conductor region 10b. Moreover, a region 17a represents a region of the metal film 15 near the connected portion between the metal film 15 and the semiconductor region 10a, and further, the region 17f represents a region of the metal film 16 near the connected portion between the metal film 16 and the conductor region 10b.

Lines in the regions 17a, 17d, 17e, and 17f show Fermi levels in the regions, respectively. Upper lines in the regions 17b and 17c show lower energy levels in a conductive band whereas lower lines show upper energy levels in a valence band.

FIG. 3 (a) shows a band structure in a thermal equilibrium state in which no voltage is applied to the transistor 100. Since the regions 17b and 17c are the semiconductor regions, band gaps exist in the semiconductor regions 17b and 17c, and therefore, no electron is moved from the region 17a to the region 17d. Incidentally, FIG. 3 (a) shows a flat band state. The thermal equilibrium state need not be a flat band state as long as there is no remotion of an electron between the region 17a and the region 17d.

FIG. 3 (b) shows a band structure in which a drain voltage is applied for positive bias. At this time, a source potential and a gate potential are set to the GND (ground). The energy levels in the regions 17b, 17c, 17d, and 17e are inclined by applying the drain voltage. Even in this state, an electron is suppressed from being moved from a source to a drain by the effect of a Schottky barrier existing near the source side end 10S of the graphene film 10 (i.e., near the boundary between the regions 17a and 17b), and therefore, the transistor 100 is kept cut off. The inclinations of Fermi levels in the regions 17a and 17f inside of the metal films 15 and 16 are omitted from being shown.

FIG. 3 (c) shows a band structure in which the drain voltage and a gate voltage are applied for positive bias. The energy levels in the regions 17c and 17d are shifted downward in FIG. 3 by applying the gate voltage. At this time, the energy band in the semiconductor region 10a is curved, and then, an electron tunnels through the Schottky barrier. Such a tunnel process via the Schottky barrier deformed into a triangle caused by the curve of the band is called an FN (Fowler-Nordheim) tunnel.

The electron tunneling through the Schottky barrier is moved toward the drain through the regions 17d and 17e inside of the conductor region 10b. Here, the electron has a very high mobility inside of the conductor region 10b, and therefore, can be moved toward the drain at a high speed. Consequently, the transistor 100 can exhibit a high current drive force.

Incidentally, since the mobility of the electron inside of the conductor region 10b is greater than that at the conductive band in the semiconductor region 10a, the length of the semiconductor region 10a in the channel direction should be preferably as short as possible within a range in which the satisfactory cut-off characteristics can be secured.

In the case where the width of the gate side wall 14 (i.e., the width of the region 17b) is wide, the energy band in the semiconductor region 10a at the time of the application of the gate voltage is moderately curved, and therefore, the gate voltage for allowing the electron to tunnel becomes large. As a consequence, in the case where the threshold voltage of the transistor 100 is made small, it is necessary to prevent the width of the gate side wall 14 from becoming too wide.

On the other hand, when the source side end 10S in the semiconductor region 10a (i.e., the position of the Schottky contact) is located on the drain side beyond the source side end 12S of the gate electrode 12 (on the right in FIGS. 2A and 2B), the energy band in the semiconductor region 10a at the time of the application of the gate voltage is slightly curved. As a consequence, the source side end 10S in the semiconductor region 10a should be preferably located immediately under the source side end 12S of the gate electrode 12 (refer to FIG. 2B), or on the source side beyond the source side end 12S of the gate electrode 12 (refer to FIG. 2A).

In this manner, the electron is suppressed from being moved from the source to the drain by the effect of the Schottky barrier in the state in which no gate voltage is applied (i.e., an off state); in contrast, the electron tunnels through the Schottky barrier so that a current flows from the source to the drain in the state in which the gate voltage is applied (i.e., an on state). Thus, the transistor 100 has the high cut-off characteristics owing to a switching operation utilizing the above-described Schottky contact.

Here, FIGS. 3(a) to 3 (c) show the band structure in the case of the transistor 100 has an n type. Also in the case of a p-type transistor, a similar switching operation can be obtained by reversing the polarity of each of the drain voltage and the gate voltage.

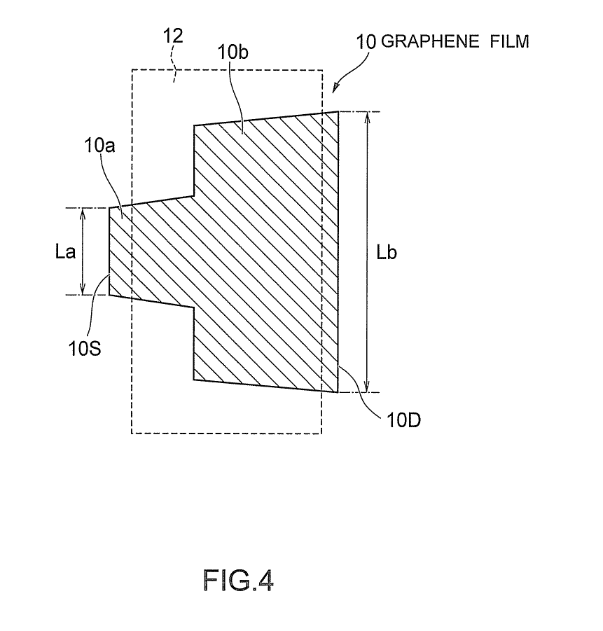

FIG. 4 is a top view exemplifying another pattern shape of the graphene film 10. The difference from the pattern shape shown in FIG. 2A resides in variations in width in the channel width direction of each of a semiconductor region 10a and a conductor region 10b according to the position in a channel direction. Also in this case, a width La of the semiconductor region 10a at a source side end 10S in the channel width direction is narrower than a width Lb of the conductor region 10b at a drain side end 10D in the channel width direction.

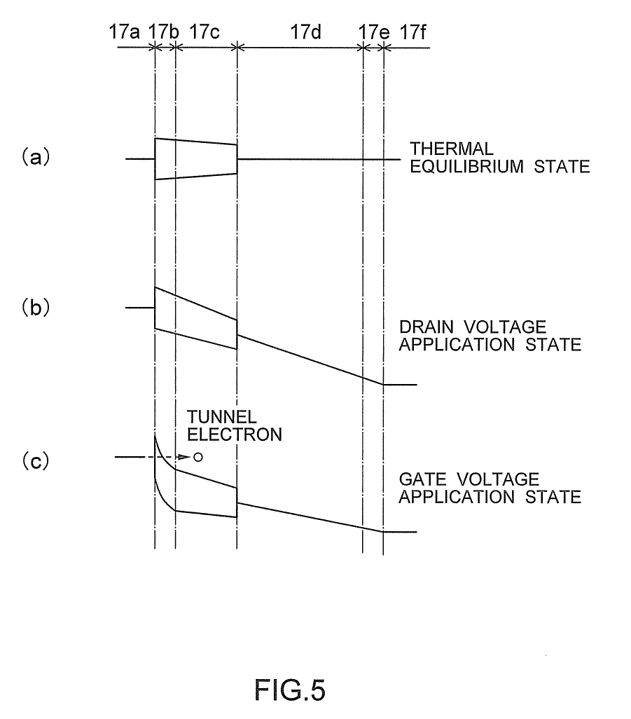

FIGS. 5 (a) to 5(c) are diagrams schematically illustrating a band structure of the graphene film 10 shown in FIG. 4.

FIG. 5 (a) shows a band structure in a thermal equilibrium state in which no voltage is applied to the transistor 100. Since the width of the semiconductor region 10a depends upon the position in the channel direction, the size of a band gap of each of regions 17b and 17c also depends upon the position in the channel direction.

FIG. 5 (b) shows a band structure in which a drain voltage is applied. Energy levels in the regions 17b, 17c, 17d, and 17e are inclined by applying the drain voltage. Also in this state, an electron is suppressed from being moved from a source to a drain by the effect of the Schottky barrier existing near the source side end 10S of the graphene film 10 (i.e., near the boundary between the regions 17a and 17b), and therefore, the transistor 100 is kept cut off.

FIG. 5 (c) shows a band structure in which the drain voltage and a gate voltage are applied. Energy levels in the regions 17c and 17d are shifted downward in FIG. 5 by applying the gate voltage. At this time, the energy band in the region 17b is curved, and then, an electron tunnels through the Schottky barrier.

Incidentally, even in the case where the width of the semiconductor region 10a in the channel width direction is varied according to the position in the channel direction, it is preferable that the width of the source side end 10S in the channel width direction should be narrowest in order to efficiently generate an FN tunnel. Moreover, all of the regions other than the semiconductor region 10a in the graphene film 10 need be conductive so as to obtain a higher current drive force, and therefore, the width of the graphene film 10 should be preferably narrowest at the source side end 10S in the graphene film 10.

In this manner, also in the case where the graphene film 10 has the pattern shape shown in FIG. 4, the transistor 100 can perform a switching operation utilizing the Schottky contact.

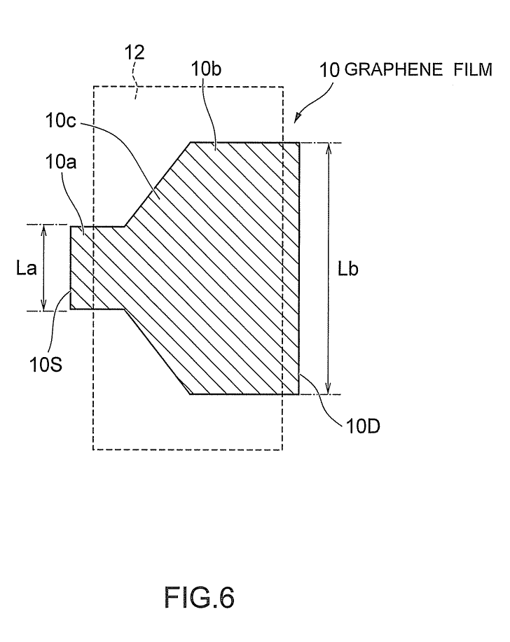

FIG. 6 is a top view exemplifying a further pattern shape of a graphene film 10. The difference from the pattern shape shown in FIG. 2A resides in a region 10c formed between a semiconductor region 10a and a conductor region 10b. Also in this case, a width La in the semiconductor region 10a at a source side end 10S in the channel width direction is narrower than a width Lb in the conductor region 10b at a drain side end 10D in the channel width direction.

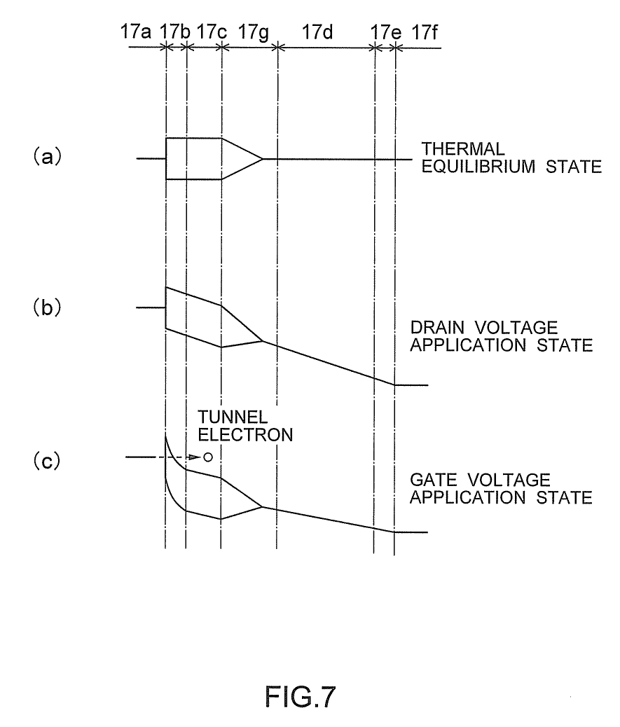

FIGS. 7 (a) to 7 (c) are diagrams schematically illustrating a band structure of the graphene film 10 shown in FIG. 6. In FIGS. 7 (a) to 7 (c), a region 17g corresponds to the region 10c of the graphene film 10.

FIG. 7(a) shows a band structure in a thermal equilibrium state in which no voltage is applied to the transistor 100. In this example, the region 10c exhibits semiconductive properties on a source side whereas conductive properties on a drain side.

FIG. 7 (b) shows a band structure in which a drain voltage is applied. Energy levels in the regions 17b, 17c, 17d, 17e, and 17g are inclined by applying the drain voltage. Also in this state, an electron is suppressed from being moved from a source to a drain by the effect of the Schottky barrier existing near the source side end 10S of the graphene film 10 (i.e., near the boundary between the regions 17a and 17b), and therefore, the transistor 100 is kept cut off.

FIG. 7(c) shows a band structure in which the drain voltage and a gate voltage are applied. Energy levels in the regions 17c, 17d, and 17g are shifted downward in FIG. 7 by applying the gate voltage. At this time, the energy band in the region 17b is curved, and then, an electron tunnels through the Schottky barrier.

In this manner, also in the case where the graphene film 10 has the pattern shape shown in FIG. 6, the transistor 100 can perform a switching operation utilizing the Schottky contact.

### (Manufacture of Transistor)

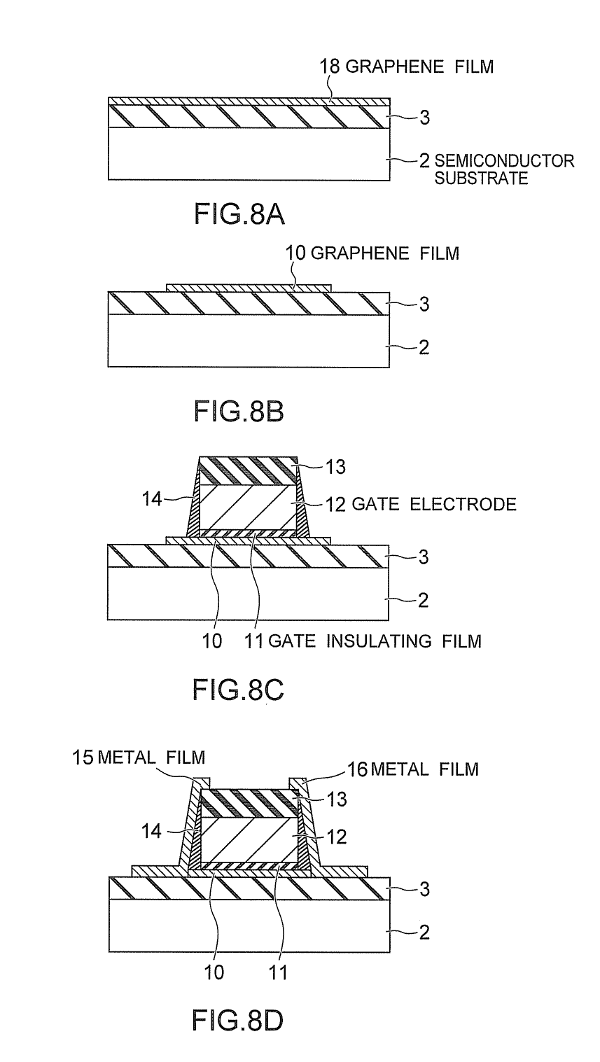

FIGS. 8A to 8D are cross-sectional views illustrating a process for manufacturing a transistor 100 in the embodiment according to the present invention.

As illustrated in FIG. 8A, an insulating film 3 and a graphene film 18 are formed on a semiconductor substrate 2.

For example, a SiO₂ film having a thickness of 30 nm is formed as the insulating film 3 by subjecting the surface of the semiconductor substrate 2 to thermal oxidization. Subsequently, a Si layer having a thickness of 3 nm is formed on the insulating film 3 by the CVD (Chemical Vapor Deposition), and then, fullerene is deposited on the Si layer by molecular beam epitaxy (i.e., the MBE). Thereafter, a SIC layer is formed by annealing the Si layer and fullerene at a temperature of 1000° C. in a high vacuum. Furthermore, the graphene film 18 is obtained by annealing the SIC layer at a temperature of 1200° C. in a high vacuum.

Next, as illustrated in FIG. 8B, the graphene film 18 is patterned into the graphene film 10 having any of the patterns illustrated in FIGS. 2A, 2B, 4, and 6.

For example, a SiO₂ film having a thickness of 30 nm is formed on the graphene film 18 by the CVD.

Next, a resist mask having the pattern of the graphene film 10 is formed on the SiO₂ film by photolithography. And then, the pattern of the resist mask is transferred by etching the SiO₂ film and the graphene film 18 by the RIE (Reactive Ion Etching). At this time, an oxygen plasma is used in etching the graphene film 18. Thereafter, the resist mask and the SiO₂ film are removed.

Subsequently, as illustrated in FIG. 8C, a gate insulating film 11, a gate electrode 12, a cap film 13, and a gate side wall 14 are formed.

For example, a SiO₂ film having a thickness of 3 nm is formed on the graphene film 10 and the insulating film 3 by the CVD. And then, a P-doped polycrystal Si film having a thickness of 50 nm is formed on the SiO₂ film by the CVD. Next, a SiN film having a thickness of 30 nm is formed on the polycrystal Si film by the CVD. Thereafter, the SiN film, the polycrystal Si film, and the SiO₂ film are etched by the RIE by using the resist having a gate pattern formed thereon by the lithography as a mask, to be processed into the cap layer 13, the gate electrode 12, and the gate insulating film 11, respectively. Subsequently, a SiO₂ film having a thickness of 5 nm is formed over the entire surface of the semiconductor substrate 2 by the CVD. And then, the SiO₂ film is anisotropically etched by the RIE, to be processed into the gate side wall 14.

Subsequently, as illustrated in FIG. 8D, metal films 15 and 16 to be connected to the graphene film 10 are formed.

For example, a Pd film having a thickness of 5 nm is formed over the entire surface of the semiconductor substrate 2 by the PVD (Physical Vapor Deposition). Thereafter, the Pd film is etched by the RIE by using the resist having a pattern of a contact electrode formed thereon by the lithography as a mask, to be processed into the metal films 15 and 16.

The metal films 15 and 16 illustrated in FIG. 8 are formed after the graphene film 10 is etched by using the cap layer 13 and the gate side wall 14 as the masks. However, they may be formed without etching the graphene film 10. Also in this case, a current flows directly in a region under the gate side wall 14 in the graphene film 10 from the metal films 15 and 16, and therefore, no influence exerts on the switching operation by the transistor 100.

Thereafter, contact plugs are connected to the gate electrode 12 and the metal films 15 and 16, respectively, although not illustrated.

In the embodiment according to the present invention, the Schottky contact between the metal film 15 and the semiconductor region 10a is utilized for the switching operation, and thus, the transistor 100 can exhibit the high current drive force and the excellent cut-off characteristics.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A transistor comprising:
a substrate;
a source electrode formed on the substrate;
a drain electrode formed on the substrate;
a graphene film formed between the source electrode and the drain electrode, the graphene film having a semiconductor region including a source side end and a conductor region including a drain side end, a width of the source side end of the graphene film in a channel width direction being narrower than a width of the drain side end of the graphene film in the channel width direction; and
a gate electrode formed via a gate insulating film on the semiconductor region of the graphene film and the conductor region of the graphene film,
wherein the source electrode is connected to the source side end of the graphene film with a Schottky contact, and the drain electrode is connected to the drain side end of the graphene film with an ohmic contact.

2. The transistor according to claim 1, wherein the source side end of the graphene film is located immediately under a source side end of the gate electrode, or on a source side beyond a source side end of the gate electrode.

3. The transistor according to claim 1, wherein the semiconductor region has a band gap of 0.3 eV or more.

4. The transistor according to claim 1, wherein the width of the source side end of the graphene film in the channel width direction is narrower than 10 nm whereas the width of the drain side end of the graphene film in the channel width direction is 10 nm or wider.

5. The transistor according to claim 1, wherein a width of the graphene film in the channel width direction is narrowest at the source side end of the graphene film.

6. The transistor according to claim 5, wherein the width of the graphene film in the channel width direction becomes narrower as a position in the channel direction approaches the source end.

7. The transistor according to claim 5, wherein the source side end of the graphene film is located immediately under a source side end of the gate electrode, or located on a source side beyond the source side end of the gate electrode.

8. The transistor according to claim 5, wherein the semiconductor region has a band gap of 0.3 eV or more.

9. The transistor according to claim 5, wherein the width of the source side end of the graphene film in the channel width direction is narrower than 10 nm whereas the width of the drain side end of the graphene film in the channel width direction is 10 nm or wider.

10. The transistor according to claim 1, further comprising a connection region between the semiconductor region and the conductor region.

11. The transistor according to claim 10, wherein the connection region includes a source side end having semiconductive properties and a drain side end having conductive properties.

12. The transistor according to claim 10, wherein the source side end of the graphene film is located immediately under a source side end of the gate electrode, or on a source side beyond a source side end of the gate electrode.

13. The transistor according to claim 10, wherein the semiconductor region has a band gap of 0.3 eV or more.

14. The transistor according to claim 10, wherein the width of the source side end of the graphene film in the channel width direction is narrower than 10 nm whereas the width of the drain side end of the graphene film in the channel width direction is 10 nm or wider.
